(19) United States
(12) Patent Application Publication
(10) Pub. No.: US 2018/0330883 A1
(43) Pub. Date: Nov. 15, 2018

(54) CAPACITOR AND METHOD FOR MANUFACTURING THE SAME

(71) Applicant: Panasonic Intellectual Property Management Co., Ltd., Osaka (JP)

(72) Inventor: MASAHITO SANO, Shimane (JP)

(21) Appl. No.: 16/040,611

(22) Filed: Jul. 20, 2018

Related U.S. Application Data
(63) Continuation of application No. PCT/JP2017/005042, filed on Feb. 13, 2017.

(30) Foreign Application Priority Data
Feb. 19, 2016 (JP) 2016-030328

(51) Int. Cl. H01G 4/236; H01L 49/02; H01G 4/005; H01G 4/224; H01G 4/252

(52) U.S. Cl. CPC H01G 4/236; H01L 28/60; H01G 4/252; H01G 4/224; H01G 4/005

(57) ABSTRACT

A film capacitor includes a capacitor element, and a pair of lead wire terminals connected to respective end face electrodes formed on both end faces of the capacitor element, the pair of lead wire terminals having a length for soldering to a printed board. The pair of lead wire terminals each includes a conductive core material, a first plating part coating a peripheral surface of the core material and making adhesion of solder favorable, and a second plating part coating at least a part of both half surface areas defined by dividing a distal surface of the core material at a center of the distal surface and making adhesion of solder favorable. The second plating part continues from the first plating part and extends on a center side of the distal surface.

### BACKGROUND

### 1. Technical Field

The present disclosure relates to a capacitor and a method for manufacturing the capacitor.

### 2. Description of the Related Art

Conventionally, a film capacitor has been known in which lead wire terminals are connected to respective both end faces of a capacitor element and the capacitor element is coated with a resin (see Patent Literature 1). When such a film capacitor is mounted on a printed board, the lead wire terminals are connected to a printed board (circuit pattern on a board back face) by soldering. Herein, the lead wire terminal can have a structure in which a periphery of a conductive core material such as copper is plated by a material that makes adhesion of solder favorable, such as tin. The lead wire terminal is cut to have a length suitable for connection by soldering before being mounted on the printed board. Accordingly, a distal surface that is a cut surface of the lead wire terminal becomes a state in which the core material is exposed.

### CITATION LIST

### Patent Literature

PTL 1: Unexamined Japanese Patent Publication No. H05-055080

### SUMMARY

When a lead wire terminal is soldered on a printed board, a peripheral surface of a distal end of the lead wire terminal is covered with solder, and a fillet is formed at the distal surface of the lead wire terminal so as to be exposed.

In contrast, in order to firmly fix the film capacitor to the printed board, it is conceivable that not only the distal end but also the distal surface of the lead wire terminal is covered with solder to increase the soldering strength of the lead wire terminal to the printed board.

However, since the distal surface of the lead wire terminal is not subjected to plating, there is a risk in that adhesiveness (adhesion property) of solder to the distal surface is bad to fail to sufficiently increase strength of soldering.

In light of the problem, the present disclosure aims to provide a capacitor that enables firm fixation to a printed board, and a method for manufacturing the capacitor.

A capacitor according to a first aspect of the present disclosure includes a capacitor element and a pair of lead wire terminals. The pair of lead wire terminals is connected to respective end face electrodes formed on both end faces of the capacitor element. Furthermore, the pair of lead wire terminals is formed to have a length for soldering to a printed board. Herein, the lead wire terminal includes a conductive core material, a first plating part, and a second plating part. The first plating part coats a peripheral surface of the core material. The first plating part is provided to make adhesion of solder favorable. The second plating part coats at least a part of both half surface areas defined by dividing a distal surface of the core material at a center of the distal surface. The second plating part is provided to make adhesion of solder favorable. The second plating part continues from the first plating part and extends on a center side of the distal surface.

A method for manufacturing a capacitor according to a second aspect of the present disclosure includes a capacitor forming process and a terminal cutting process. The capacitor forming process is a process of forming a capacitor including a capacitor element and a pair of lead wire terminals connected to respective end face electrodes formed on both end faces of the capacitor. Herein, the pair of lead wire terminals each includes a conductive core material and a first plating part coating a peripheral surface of the core material and making adhesion of solder favorable. The terminal cutting process is a process of cutting the pair of lead wire terminals to have a predetermined length. Herein, in the terminal cutting process, each of the lead wire terminals is sandwiched and cut by two blades to make a part of the first plating part extend on a cut surface of the core material by the two blades to form a second plating part coating at least a part of the cut surface.

The present disclosure makes it possible to firmly fix the capacitor to a printed board.

Effects or meanings of the present disclosure will be further clarified in the following description of the exemplary embodiment. However, the exemplary embodiment described below is merely an example of implementing the present disclosure, and the present invention is not at all limited to the following exemplary embodiment.

### BRIEF DESCRIPTION OF THE DRAWINGS

FIG. 1A is a perspective view of a film capacitor according to an exemplary embodiment;

FIG. 1B is a vertical cross-sectional view of the film capacitor cut at a position of lead wire terminals according to the exemplary embodiment;

FIG. 1C is an enlarged view of part A in FIG. 1B according to the exemplary embodiment;

FIG. 1D is a diagram illustrating a distal surface of the lead wire terminal according to the exemplary embodiment;

FIG. 2 is diagram illustrating a state where the film capacitor is mounted on a printed board;

FIG. 3 is a flow chart illustrating a manufacturing process of the film capacitor according to the exemplary embodiment;

FIG. 4 is a schematic view for describing a capacitor forming process according to the exemplary embodiment;

FIG. 5 is a schematic view for describing a terminal cutting process according to the exemplary embodiment; and

FIG. 6 is a schematic view for describing a mechanism of forming a second plating part on a distal surface (cut surface) of a core material of the lead wire terminal according to the exemplary embodiment.

### DETAILED DESCRIPTION

Hereinafter, an exemplary embodiment of the present disclosure will be described with reference to the drawings.

In the exemplary embodiment, film capacitor 1 corresponds to “capacitor” described in claims. Furthermore, first plating part 22 and second plating part 23 respectively correspond to “first plating part” and “second plating part” described in claims.

However, the above-mentioned description only aims to correlate the structure in claims and the structure in the exemplary embodiment, and the above-mentioned correlation does not limit the invention described in claims to the structure of the exemplary embodiment.

### <Structure of Film Capacitor>

First, film capacitor 1 of the exemplary embodiment will be described.

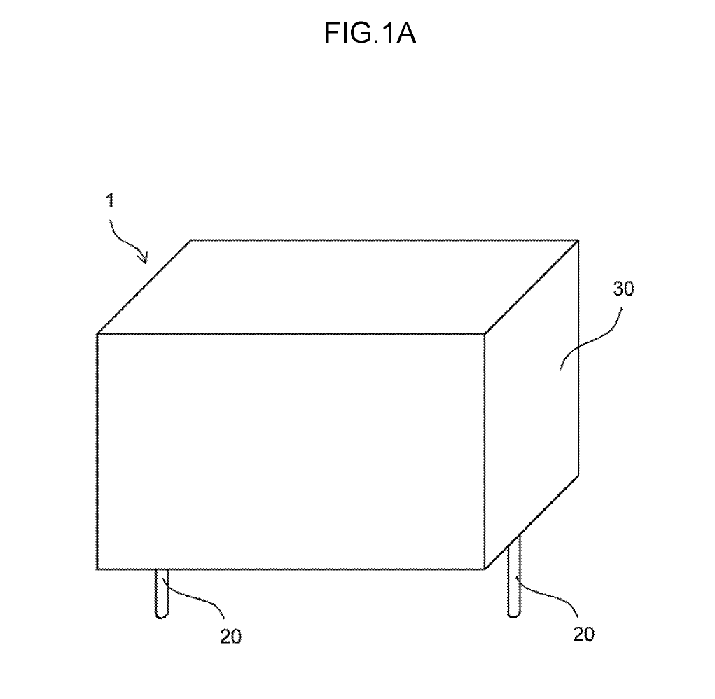

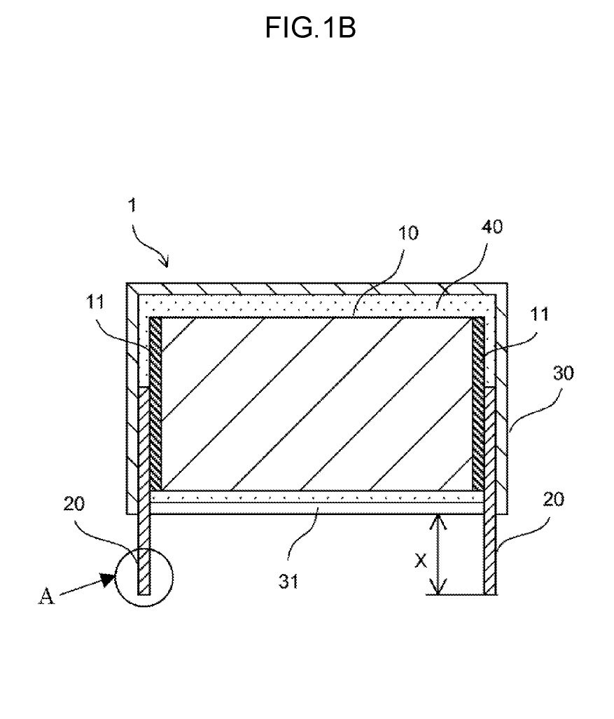

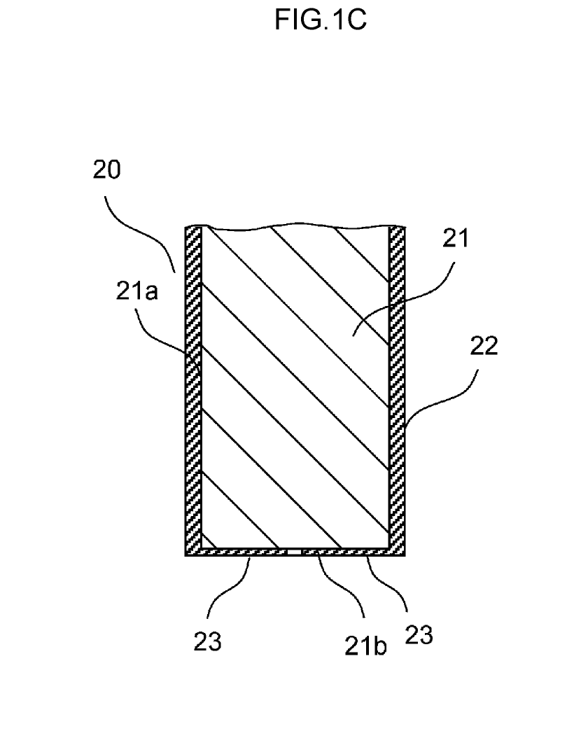

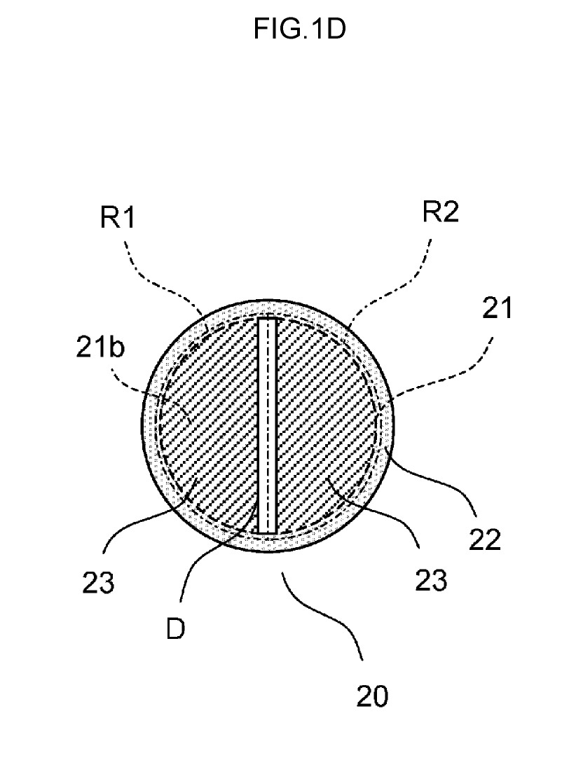

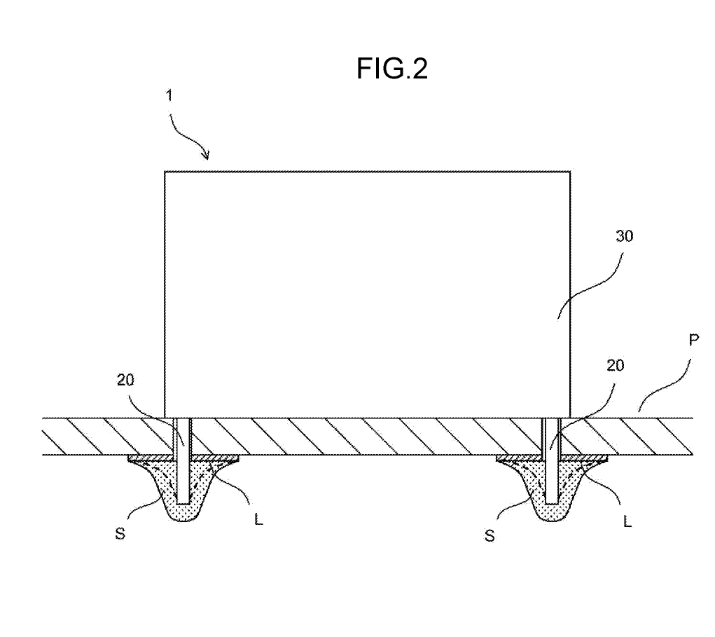

FIG. 1A is a perspective view of film capacitor 1 and FIG. 1B is a vertical cross-sectional view of film capacitor 1 cut at a position of lead wire terminals 20 according to the exemplary embodiment. FIG. 1C is an enlarged view of part A in FIG. 1B according to the exemplary embodiment, and FIG. 1D is a diagram illustrating a distal surface of lead wire terminal 20 according to the exemplary embodiment. Furthermore, FIG. 2 is a diagram illustrating a state where film capacitor 1 is mounted on printed board P according to the exemplary embodiment. Note that, in FIG. 1D, first plating part 22 is subjected to gray coloring and slushes are attached to second plating part 23 for convenience. Furthermore, in FIG. 2, printed board P and solder S are illustrated in a cross-sectional view for convenience.

As illustrated in FIG. 1A and FIG. 1B, film capacitor 1 includes capacitor element 10, a pair of lead wire terminals 20, case 30, and filling resin 40.

Capacitor element 10 is formed by overlapping two metallized films in which aluminum is evaporated on dielectric films, winding or laminating the overlapped metallized films, and pressing it to have a flat shape. End face electrodes 11 are formed on respective both end faces of capacitor element 10 by thermally spraying metallikon metal. Note that, although capacitor element 10 of the exemplary embodiment is formed by a metallized film in which aluminum is evaporated on a dielectric film, it may be formed by a metallized film on which another metal such as zinc, magnesium, or the like is evaporated. Alternatively, capacitor element 10 may be formed by a metal film on which a plurality of metals among the metals is evaporated, or may be formed by a metallized film on which an alloy of the metals is evaporated.

The pair of lead wire terminals 20 is connected to respective end face electrodes 11 of capacitor element 10 on their proximal end sides. Case 30 is formed in a rectangular parallelepiped box shape whose one face is opened by a resin material such as polyphenylene sulfide (PPS). Capacitor element 10 and lead wire terminals 20 are housed in case 30, and distal end sides of lead wire terminals 20 are projected outside from opening 31 of case 30. Projection length X of lead wire terminal 20 from case 30 is a length corresponding to soldering to printed board P, and for example, when a thickness of printed board P on which film capacitor 1 is mounted is about 1 mm to 1.5 mm, projection length X can be about 4 mm. Filling resin 40 is filled in case 30. Filling resin 40 covers capacitor element 10 and protects capacitor element 10 from humidity or impact.

As illustrated in FIG. 1C and FIG. 1D, lead wire terminal 20 includes core material 21 formed of a metal material having conductivity such as cupper. Peripheral surface 21a of core material 21 is coated with first plating part 22 formed of a material such as tin that makes adhesiveness (adhesion property) of solder S favorable. Furthermore, half surface areas R1, R2 defined by dividing distal surface 21b of core material 21 at a center are coated with second plating part 23 except linear part D at the center of distal surface 21b. Second plating parts 23 are formed by parts of first plating part 22 extended when lead wire terminal 20 is cut to have projection length X in a terminal cutting process described below, and formed to continue from first plating part 22 and extend on the center side of distal surface of 21b of core material 21.

Note that not less than 50% of each of half surface areas R1, R2, that is, not less than 50% of total distal surface 21b of core material 21 is desirably coated with second plating part 23, and in the exemplary embodiment, 80% to 90% of each of half surface areas R1, R2, that is, 80% to 90% of total distal surface 21b of core material 21 is coated with second plating part 23.

As illustrated in FIG. 2, when film capacitor 1 is mounted on printed board P, lead wire terminals 20 are made to pass through respective through holes formed on printed board P and circuit pattern L provided on a back surface of printed board P, and distal ends of lead wire terminals 20 are connected to circuit pattern L by solders S. At this time, solder S becomes a fillet shape to cover the whole distal end of lead wire terminal 20. In the exemplary embodiment, lead wire terminal 20 is coated with second plating part 23 not only at peripheral surface 21a of core material 21 but also at both sides of distal surface 21b (both half surface areas R1, R2), so that adhesiveness of solder S becomes favorable with respective to the whole distal end of lead wire terminal 20. This increases soldering strength of lead wire terminal 20 to printed board P (circuit pattern L) as compared with a case of fillet shaped soldering in which the distal surface of lead wire terminal 20 is exposed from solder S as illustrated by dotted lines in FIG. 2, making it possible to firmly fix film capacitor 1 to printed board P.

### <Method for Manufacturing Film Capacitor>

Next, a method for manufacturing film capacitor 1 will be described.

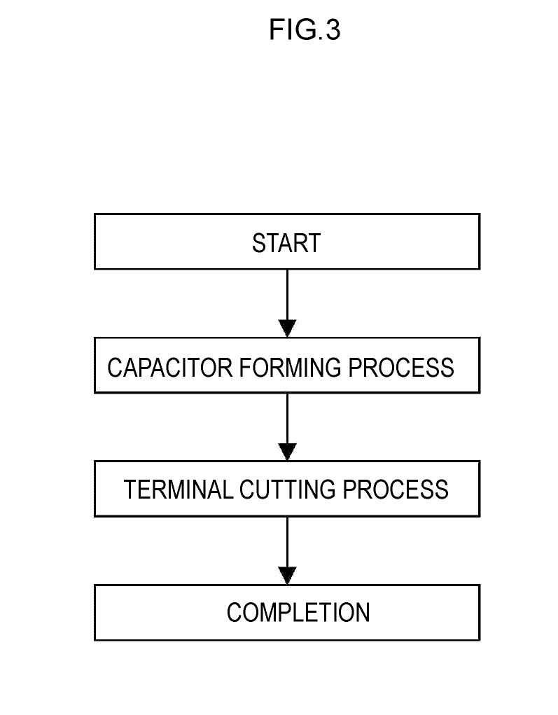

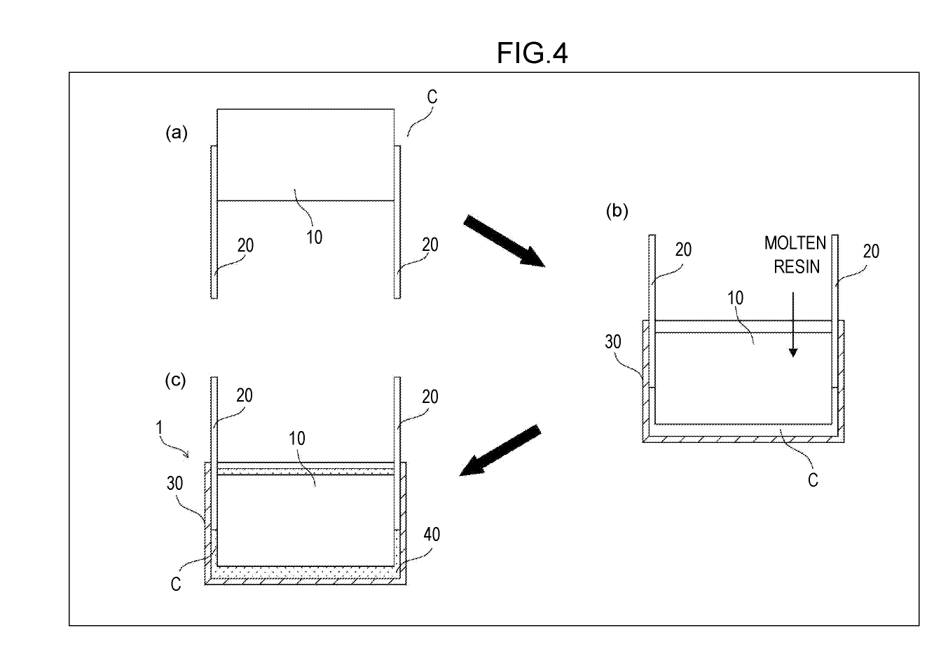

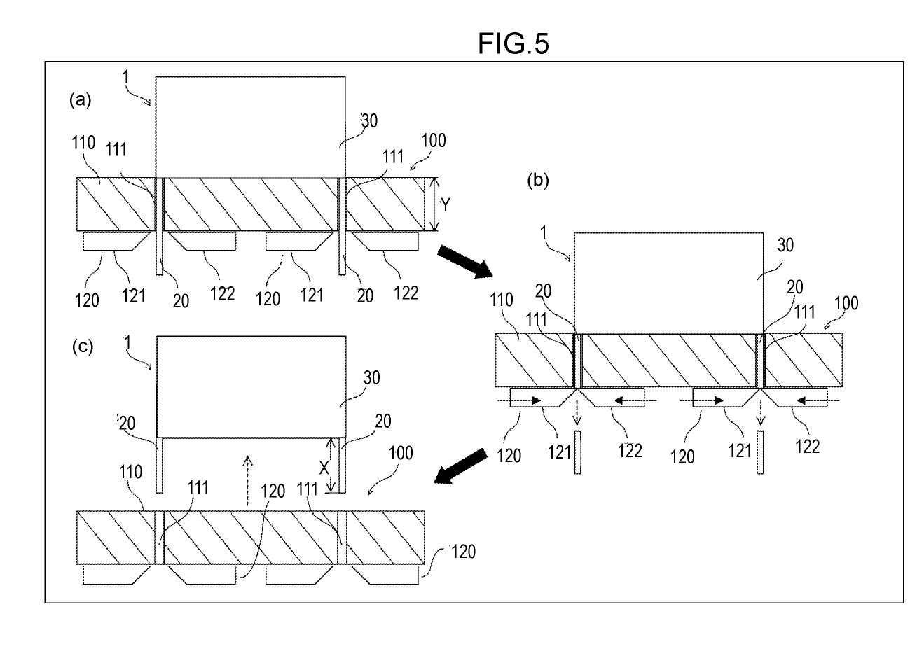

FIG. 3 is a flow chart illustrating a manufacturing process of film capacitor 1 according to the exemplary embodiment. FIG. 4 is a schematic view for describing a capacitor forming process according to the exemplary embodiment. Furthermore, FIG. 5 is a schematic view for describing a terminal cutting process according to the exemplary embodiment.

As illustrated in FIG. 3, the manufacturing process of film capacitor 1 according to the exemplary embodiment includes the capacitor forming process and the terminal cutting process.

### <Capacitor Forming Process>

First, the capacitor forming process illustrated in FIG. 4 is performed. In the capacitor forming process, first, lead wire terminals 20 are connected to respective end face electrodes 11 on the both sides of capacitor element 10 by a connection method such as soldering to form capacitor unit C (see (a) of FIG. 4). Next, capacitor unit C is housed in case 30 whose opening 31 is positioned in an upper side, and a molten resin that becomes filling resin 40 is injected in case 30 (see (b) of FIG. 4). When the molten resin is cooled and hardened, capacitor element 10 is coated with filling resin 40, and film capacitor 1 in a state where lead wire terminal 20 is longer than projection length X (in a state before being cut) is formed (see (c) of FIG. 4).

### <Terminal Cutting Process>

Next, the terminal cutting process illustrated in FIG. 5 is performed using cutting machine 100. Cutting machine 100 includes installation table 110 and two cutters 120. Thickness Y of installation table 110 is made to be substantially equal to projection length X of lead wire terminal 20 of film capacitor 1 (see FIG. 1B) in a final stage. Two though holes 111 through which respective lead wire terminals 20 are passed are formed on installation table 110. Each cutter 120 is installed right below installation table 110 to correspond to each through hole 111, and includes two opposed blades 121, 122. Two blades 121, 122 move between a state where blade edges of them are in contact and a state where the blade edges of them are separated in a direction perpendicular to a direction in which lead wire terminal 20 is projected from through hole 111 in order to cut lead wire terminal 20.

In the terminal cutting process, first, film capacitor 1 is set on installation table 110 such that lead wire terminals 20 are passed through through holes 111 (see (a) of FIG. 5). Next, cutter 120 is operated, and two blades 121, 122 move so as to be in a state where the blade edges of them are in contact. This makes lead wire terminal 20 be sandwiched by moved blades 121, 122 from both sides to be cut (see (b) of FIG. 5). Then, film capacitor 1 is taken out from installation table 110 (see (c) of FIG. 5). This completes film capacitor 1 in a final stage in which lead wire terminals 20 are cut to have projection length X.

In the terminal cutting process, in lead wire terminal 20, second plating part 23 is formed on distal surface 21b that is a cut surface of core material 21.

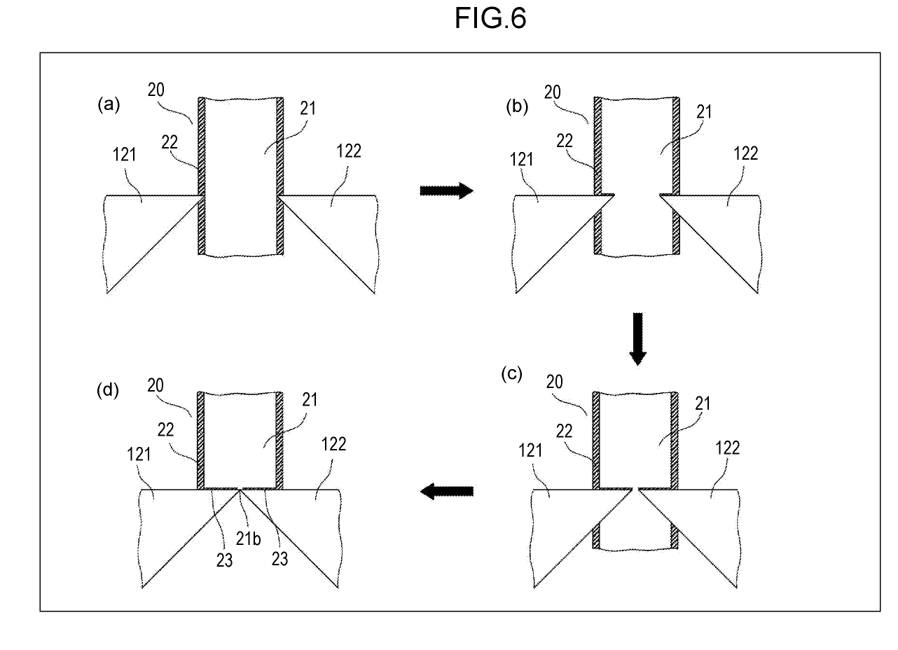

FIG. 6 is a schematic view for describing a mechanism of forming second plating part 23 on distal surface 21b (cut surface) of core material 21 of lead wire terminal 20 according to the exemplary embodiment.

Referencing to FIG. 6, when two blades 121, 122 of cutting machine 100 cut first plating part 22 of lead wire terminal 20, their blade edges shave off a part of first plating part 22 (see (a) of FIG. 6). Two blades 121, 122 move to a center of core material 21 while applying the shaved part of first plating part 22 on the cut surface of core material 21 of lead wire terminal 20 (see (b), (c) of FIG. 6). In this manner, the part of first plating part 22 is elongated to the center of the cut surface of core material 21 with movement of two blades 121, 122 to the center. When two blades 121, 122 reach the center of core material 21 to perfectly cut lead wire terminal 20, distal surface 21b that is the cut surface of core material 21 is coated with second plating part 23 formed by extension of the part of first plating part 22 (see (d) of FIG. 6). Although a coverage of distal surface 21b by second plating part 23 changes depending on the thickness of first plating part 22 or states of the blade edges of two blades 121, 122, in the exemplary embodiment, as illustrated in FIG. 1D, 80% to 90% of distal surface 21b (half surface areas R1, R2) becomes a state of being coated with second plating part 23.

### <Advantageous Effects of Exemplary Embodiment>

As described above, the following advantageous effects will be obtained.

According to film capacitor 1 of the exemplary embodiment, lead wire terminal 20 is widely coated with second plating part 23 at not only peripheral surface 21a of core material 21 but also distal surface 21b. Accordingly, in order to mount film capacitor 1 on printed board P, when soldering having a fillet shape is performed to cover the whole distal end of lead wire terminal 20, adherence of solder S to peripheral surface 21a as well as distal surface 21b becomes favorable (solder S is firmly adhered). This makes it possible to sufficiently enhance soldering strength of lead wire terminal 20 to printed board P to firmly fix film capacitor 1 to printed board P.

Furthermore, since distal surface 21b of core material 21 of lead wire terminal 20 is coated with second plating part 23 and core material 21 formed of a metal material is not exposed outside, core material 21 is prevented from being in contact with external air to be oxidized.

Furthermore, according to the method for manufacturing film capacitor 1 according to the exemplary embodiment, second plating part 23 can be formed in a wide area of distal surface 21b of core material 21 of lead wire terminal 20 by only cutting lead wire terminals 20 to have a length (projection length X) for soldering to printed board P. Thus, a redundant cost and process for forming second plating part 23 are less likely to generate, and second plating part 23 can be easily formed.

Although the exemplary embodiment of the present disclosure is described above, the present invention is not limited to the above exemplary embodiment, and applications of the present invention can be variously modified besides the above-mentioned exemplary embodiment.

For example, in the above-mentioned exemplary embodiment, 80% to 90% of distal surface 21b of core material 21 of lead wire terminal 20 is coated with second plating part 23. However, in order to make solder S be favorably adhered to distal surface 21b of core material 21, it is sufficient that not less than 50% of distal surface 21b is coated with second plating part 23, and second plating part 23 may be coated on whole distal surface 21b, or may be coated on an area smaller than 80% of distal surface 21b.

Furthermore, in the above-mentioned exemplary embodiment, lead wire terminal 20 is cut by cutter 120 of cutting machine 100 in an alignment direction (right and left direction in FIG. 4) of two lead wire terminals 20. However, the cutting direction of lead wire terminal 20 is not limited to the above-mentioned direction, and for example, lead wire terminal 20 may be cut by cutter 120 in a direction perpendicular to the above-mentioned alignment direction (front and back direction in FIG. 4).

Furthermore, in the above-mentioned exemplary embodiment, film capacitor 1 has a structure in which one capacitor unit C composed of capacitor element 10 and the pair of lead wire terminals 20 are housed in case 30. However, film capacitor 1 may have a structure in which a plurality of capacitor units C is housed in case 30.

Furthermore, in the above-mentioned exemplary embodiment, film capacitor 1 is exemplified as an example of the capacitor of the present disclosure. However, the present disclosure can be applied to a capacitor other than film capacitor 1, for example, such as a ceramic capacitor or an aluminum electrolytic capacitor as long as it is a lead type product for being mounted on a substrate. Furthermore, in the above-described exemplary embodiment, as an example of the method for manufacturing the capacitor of the present disclosure, the method for manufacturing film capacitor 1 is exemplified. However, the present disclosure can be applied to a method for manufacturing a capacitor other than the method for manufacturing film capacitor 1, for example, a method for manufacturing a ceramic capacitor or an aluminum electrolytic capacitor as long as it is a method for manufacturing a lead type product for being mounted on a substrate.

Besides, the exemplary embodiment of the present disclosure can be variously modified appropriately within the technical idea described in claims.

The present disclosure is useful for a capacitor for use in various electronic devices, electronic equipment, industrial equipment, electrical components for a vehicle, and the like, and a method for manufacturing the capacitor.

What is claimed is:

1. A capacitor comprising:
a capacitor element; and
a pair of lead wire terminals connected to respective end face electrodes on both end faces of the capacitor element, the pair of lead wire terminals having a length for soldering to a printed board,
wherein the pair of lead wire terminals each includes
a conductive core material,
a first plating part coating a peripheral surface of the core material and making adhesion of solder to the peripheral surface favorable, and
a second plating part coating at least a part of each of half surface areas defined by dividing a distal surface of the core material at a center of the distal surface and making adhesion of solder favorable, and
the second plating part continues from the first plating part and extends toward a center of the distal surface.

2. The capacitor according to claim 1, wherein each of the pair of lead wire terminals is coated with the second plating part in an area of not less than 50% of each of the half surface areas.

3. A method for manufacturing a capacitor comprising:
a capacitor forming process of forming a capacitor including a capacitor element and a pair of lead wire terminals connected to respective end face electrodes formed on both end faces of the capacitor, the pair of lead wire terminals each including a conductive core material and a first plating part coating a peripheral surface of the core material and making adhesion of solder to the peripheral surface favorable; and
a terminal cutting process of cutting the pair of lead wire terminals to have a predetermined length,
wherein, in the terminal cutting process, each of the pair of lead wire terminals is sandwiched and cut by two blades to make a part of the first plating part extend on a cut surface of the core material by the two blades to form a second plating part coating at least a part of the cut surface.

4. The method for manufacturing a capacitor according to claim 3, wherein not less than 50% of the cut surface is coated with the second plating part.
